(19) United States
(12) Patent Application Publication
(10) Pub. No.: US 2009/0073656 A1
(43) Pub. Date: Mar. 19, 2009

(54) HEAT SINK, HEAT SINK FAN, AND METHOD FOR MANUFACTURING THE SAME

(75) Inventors: Takaya OTSUKI, Kyoto (JP); Takamasa YAMASHITA, Kyoto (JP); Tatsuya AKASE, Kyoto (JP); Akira HIRAKAWA, Kyoto (JP)

Correspondence Address: NIDEC CORPORATION;c/o KEATING & BENNETT, LLP, 1800 Alexander Bell Drive, SUITE 200, Reston, VA, 20191, US

(73) Assignee: NIDEC CORPORATION, Minami-ku (JP)

(21) Appl. No.: 11/961,050

(22) Filed: Dec. 20, 2007

(30) Foreign Application Priority Data
Sep. 18, 2007 (JP) 2007-241600

(51) Int. Cl. H05K 7/20; B23P 15/00

(52) U.S. Cl. 361/697; 29/889.3; 361/710

(57) ABSTRACT

A heat sink has a structure which enables the heat sink to be carried by a holding device in an automated production line. The heat sink includes a base portion at a center thereof and a finned portion around the base portion. The heat sink is arranged in contact with, or very close to, an object to be cooled, e.g., an MPU, and receives the heat generated in the object. The heat is then dissipated to ambient air from the fins. At an object-side end of the heat sink is provided a convex portion which has an engagement feature to be caught by the holding device while the heat sink is carried.

### BACKGROUND OF THE INVENTION

1. Field of the Invention

The present invention relates to a fan with a heat sink which cools an object such as an electronic component.

2. Description of the Related Art

High-performance electronic devices such as computers and game players include various electronic components, e.g., micro processing units (hereinafter, referred to as MPUs). MPUs are key components of the high-performance electronic devices, and process commands or data externally input thereto and carry out various operations, e.g., such as controlling external devices or display images. Processing speeds of MPUs have rapidly increased in recent years and, along with this, the amount of heat generation in MPUs have also increased, resulting in a temperature rise in an MPU's operating environment. This temperature rise, however, may cause malfunctions or failures MPUs. Thus, it is one of critical issues, in order to achieve stable operations of electronic devices using MPUs, how efficiently the MPUs as heat sources are cooled.

A surface of an MPU is usually made of material which is good in thermal conductivity, e.g., ceramic, and a heat sink is arranged in contact with the surface of the MPU so as to allow the heat generated in the MPU to be transferred to the heat sink. The heat sink is usually made of metal having high thermal conductivity in order to provide higher cooling performance, and has a plurality of thin-plates which are also called as “fins” in order to enlarge the surface area of the heat sink. The heat sink and a fan for sending air to the heat sink are combined into a unit which may be called as a “heat sink fan”. The heat sink fan is attached to an MPU.

A heat sink usually includes a base portion, which is centered about a center axis and is symmetrical with the center axis, e.g., approximately columnar, and a finned portion around the base portion. The finned portion includes a plurality of fins. The heat sink is arranged with the surface of the base portion in contact with the MPU, thereby receiving the heat generated in the MPU. The received heat is diffused into the finned portion. In this manner, the MPU is cooled. In order to increase the cooling efficiency of the heat sink, it is necessary to enlarge the surface area of the finned portion. This can be achieved by radially arranging the fins such that the thickness of each fin is reduced as it moves away from the base portion and is minimized at its distal end, i.e., an end opposite to the base portion. With this configuration, the heat transferred to the surface of the base portion is transferred to the outer periphery of the finned portion and is then radiated from the surfaces of the fins to ambient air. However, reduction in the thickness of each fin at its distal end lowers the strength of the heat sink. For this reason, reduction in the fin thickness has a limitation.

Heat sink fans are usually manufactured in automated manufacturing lines. For example, in the automated manufacturing line, heat sinks placed on a tray are grasped by a holding device and carried one by one to a position at which a fan to be assembled is placed. Then, the carried heat sink is assembled with the fan so as to form a heat sink fan. The heat sink fan is then automatically carried to a stage where it is attached to a substrate with an electronic component, e.g., an MPU mounted thereon.

In order to efficiently carry the heat sinks in the above automated manufacturing lines, each heat sink must have a grasped portion at which the holding device can easily grasp the heat sink.

The grasped portion may be provided on the outer periphery of each heat sink. In this case, however, there remains a problem of insufficient strength of the heat sink during transportation thereof, because the outer periphery of the finned portion is formed by the thinnest portions of the respective fins. Moreover, the grasped portion on the outer periphery of the finned portion may be hid by the fan after the fan is mounted on the heat sink. Furthermore, the grasped portion may be provided as a separate member from the heat sink. However, this increases the number of the components and assembling steps.

### SUMMARY OF THE INVENTION

According to preferred embodiments of the present invention, a heat sink for cooling an object is provided. The heat sink includes a base portion centered about a center axis, and a finned portion including a plurality of fins arranged about the center axis. The fins extend outward from the base portion in a radial direction that is perpendicular to or substantially perpendicular to the center axis. A convex portion is formed at one of axial ends of the heat sink. The convex portion is formed by at least a raised portion of the base portion and is provided, on an outer peripheral surface thereof, with a projection projecting away from the center axis.

The convex portion may be formed by the raised portion of the base portion at one of axial ends thereof without including the finned portion. Alternatively, the convex portion may be formed by the raised portion of the base portion and a raised portion of the finned portion. In the latter case, an outer periphery of the convex portion may be defined by outer periphery of the raised portion of the finned portion.

The convex portion may have a substantially rectangular shape when viewed along the axial direction. Alternatively, the convex portion may have an approximately rectangular shape with corners that are round-chamfered when viewed along the axial direction, or an approximately rectangular shape with corners that are chamfered at approximately 45 degrees, when viewed along the axial direction.

Each of the fins of the finned portion may be split into two or more at a split point between its radially inner end and its radially outer end. It is preferable that no split point be included in the convex portion.

The base portion may include a columnar portion and a surrounding portion surrounding the columnar portion. The columnar portion projects from the surrounding portion and has smaller surface roughness at its axial end than that of an axial end of the surrounding portion.

A recess may be arranged axially between the projection and a remaining portion of the base portion, a diameter of the heat sink being longer at the projection than at the recess. The recess may be arranged over a portion of a circumferential length of the heat sink. In addition, the diameter of the heat sink is longer than the projection than at the recess by an approximately constant difference.

According to another preferred embodiment of the present invention, a heat sink fan includes the aforementioned heat sink and a fan supplying an air flow to the heat sink. The fan includes an impeller rotatable about a rotation axis and having a plurality of blades generating the air flow while the impeller is rotating; a motor operable to drive the impeller; and a housing having a surrounding wall portion which surrounds the impeller from outside in the radial direction and supports the motor. The heat sink and the fan are arranged with the center axis of the base portion and the rotation axis of the impeller substantially coaxial with each other.

As described above, according to the preferred embodiments of the present invention, a heat sink is provided which allows the heat sink or a heat sink fan obtained by assembling the heat sink with a fan to be easily carried via a holding device provided in an automated manufacturing line. With this heat sink, it is possible to assemble the heat sink fan and mount the assembled heat sink on a circuit board on which an object to be cooled, e.g., an MPU more efficiently.

The heat sink has a base portion centered about a center axis and a finned portion including a plurality of fins arranged about the center axis. The heat sink is arranged to be in contact with the object to be cooled, so that the heat generated in the object can be transferred to the heat sink and radiated to ambient air. In this manner, the heat sink contributes to dissipation of the heat of the object. The heat sink has a convex portion at one axial end of the base portion which is to be in contact with the object. The convex portion has a radial projection on its outer periphery. The heat sink is carried by being hooked at the radial projection by the holding device of the automated manufacturing line. The convex portion includes at least a raised portion of the base portion. The outer periphery of the convex portion may be formed by the raised portion of base portion only, the raised portion of the base portion and a raised portion of the finned portion, or the raised portion of the finned portion.

The heat sink of the preferred embodiments of the present invention can ensure sufficient strength of the heat sink during transportation of the heat sink or the heat sink fan. In a case where the convex portion includes the finned portion, the heat sink of the preferred embodiments of the present invention has the advantage that the convex portion can contribute to heat dissipation. Moreover, the above structure of the heat sink enables the heat sink to be hooked or caught at the same portion when the heat sink is combined with the fan and when the heat sink fan is mounted on the circuit board. Thus, it is easier to manage the manufacturing of the heat sink fan.

Other features, elements, advantages and characteristics of the present invention will become more apparent from the following detailed description of preferred embodiments thereof with reference to the attached drawings.

### BRIEF DESCRIPTION OF THE DRAWINGS

FIG. 1 is a perspective view of a heat sink according to a preferred embodiment of the present invention.

FIG. 2 is a side view of the heat sink of FIG. 1, when viewed from the outside in a radial direction thereof.

FIGS. 3, 4, 5, 6, 7, and 8 show the heat sink in the course of manufacture.

FIG. 9 is a plan view of a variant of the heat sink according to a preferred embodiment of the present invention.

FIG. 10 is a plan view of another variant of the heat sink according to a preferred embodiment of the present invention.

FIG. 11 is a side view of a heat sink fan including the heat sink of a preferred embodiment of the present invention and a fan attached to the heat sink.

FIG. 12 illustrates how to carry the heat sink fan of FIG. 11 with a holding device in an automated manufacturing line.

### DETAILED DESCRIPTION OF PREFERRED EMBODIMENTS

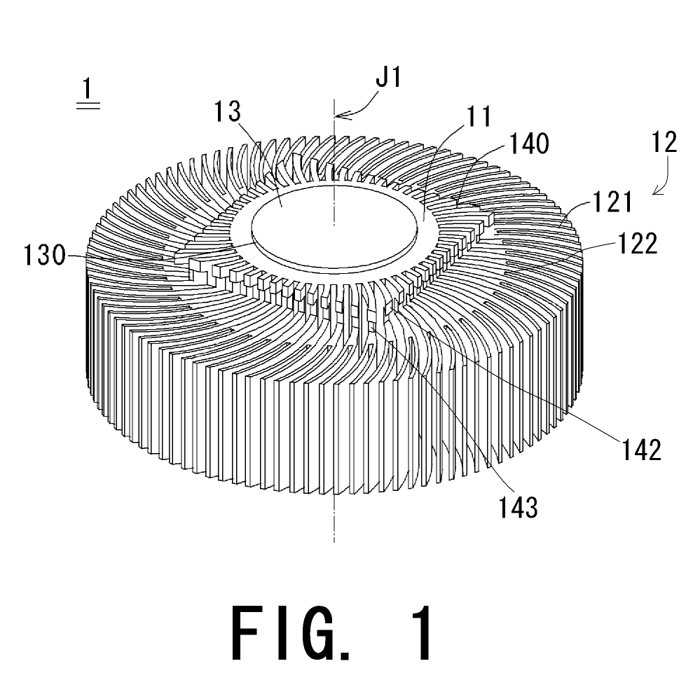

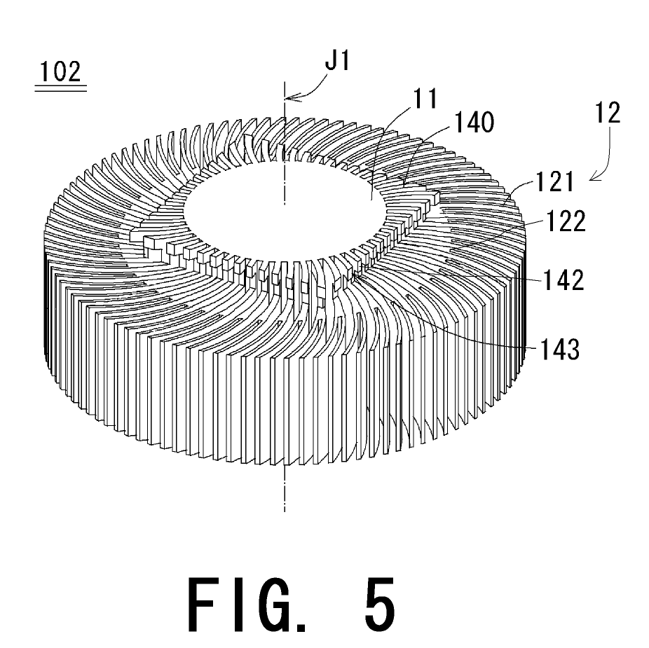

Referring to FIGS. 1 through 12, preferred embodiments of the present invention will be described in detail. It should be noted that in the explanation of the present invention, when positional relationships among and orientations of the different components are described as being up/down or left/right, ultimately positional relationships and orientations that are in the drawings are indicated; positional relationships among and orientations of the components once having been assembled into an actual device are not indicated. Meanwhile, in the following description, an axial direction indicates a direction parallel to a center axis of a heat sink, and a radial direction indicates a direction perpendicular to the center axis.

In the following description, a “heat sink” is a member for cooling an object, formed by a base portion and a finned portion. The base portion is centered about a center axis of the heat sink and is usually made of dense metal in the form of, for example, a circular or substantially circular column or a rectangular or substantially rectangular column. The finned portion is an assembly of fins, i.e., plate-like members each extending away from the center axis and continuously extending in the axial direction. An outer shape of the finned portion or a portion thereof means a shape of an envelope or a virtual plane obtained by connecting distal ends, i.e., radially outer ends of all the fins. Moreover, a cross-sectional shape of the heat sink means a cross-sectional shape of the heat sink when the heat sink is cut along a plane perpendicular to or substantially perpendicular to the center axis.

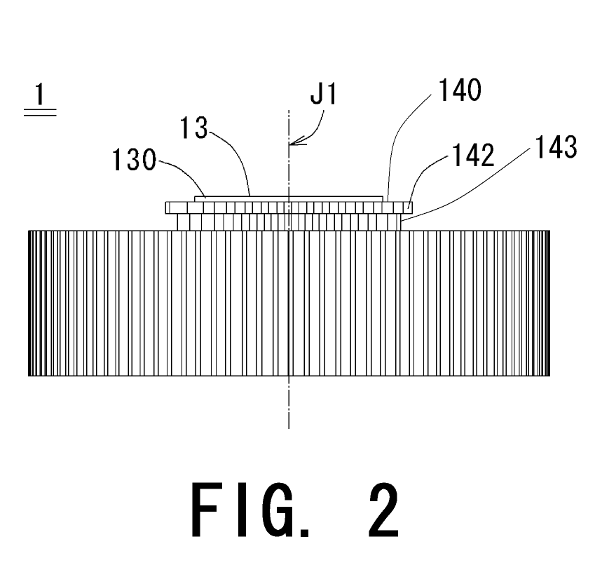

FIG. 1 is a perspective view of a heat sink according to a preferred embodiment of the present invention. FIG. 2 is a side view of the heat sink of FIG. 1 when viewed from the outside in the radial direction.

Referring to FIG. 1, the heat sink 1 includes a base portion 11 centered about a center axis J1 thereof and a finned portion 12 having a plurality of fins. The base portion 11 has a shape of a circular or substantially circular column or a rectangular or substantially rectangular column, for example. In this preferred embodiment, the base portion 11 is preferably in the form of a substantially circular column centered about the center axis J1. The fins of the finned portion 12 extend outward in the radial direction and extend continuously in the axial direction. Moreover, the fins are formed on the outer peripheral surface of the base portion 11 integrally and continuously therewith in order to increase the area of contact between the heat sink 1 and ambient air, i.e., the surface area of the heat sink 1. In addition, the fins of the finned portion 12 are spirally curved with respect to the center axis J1 when viewed along the axial direction in this preferred embodiment. This shape of the fins 12 also continues to increase the surface area of the heat sink 1. However, the shape of the fins 12 increasing the surface area of the heat sink 1 is not limited the above.

In this preferred embodiment, each fin is split at a split point 122 between its radially innermost portion and its radially outermost portion such that outer portions 121 located radially outside the split point 122 extend radially outwardly. The outer portions 121 are hereinafter referred to as “branch fins 121”. With this configuration, the surface area of the outer part of the finned portion 12, which is radially outside the split points 122, increases by about 1.5 times as compared with a case where each fin is not split.

In this preferred embodiment, the heat sink 1 is preferably formed by extrusion or drawing. Materials having relatively higher thermal conductivity are used as the material of the heat sink 1. Exemplary materials are aluminum, aluminum alloy, copper, and copper alloy. For example, the heat sink 1 is formed in the following manner. First, the material of the heat sink 1 is heated and molten. The molten material is put into a mold and is then extruded or drawn from an opening of the mold having a shape corresponding to a cross-sectional shape of the heat sink 1 perpendicularly to the opening. Please note that the cross-sectional shape is a shape on a cross section perpendicular to the center axis J1 of the heat sink 1. In this manner, the material is shaped into a block which has the same cross-sectional shape as the cross-sectional shape of the heat sink 1 but has an axial length longer than each heat sink 1. Then, after being cooled, the block is cut at a desired length and, if necessary, a cut plane is polished.

In general, in a case of performing extrusion or drawing using aluminum-based material, a mold or die can have a simple structure and high dimension precision can be achieved in a finished product, as compared with a case of using other metals. On the other hand, in a case of using copper-based material, it is difficult to obtain a desired shape by extrusion or drawing when the shape is complicated, and the dimension precision in the finished product is very low. For this reason, it is impossible to form a heat sink having a complicated shape by extrusion or drawing using copper-based material. Therefore, aluminum alloy is used as the material of the heat sink 1 of this preferred embodiment, which has a complicated structure in which the finned portion 12 is continuously formed with the base portion 11, not copper-based material.

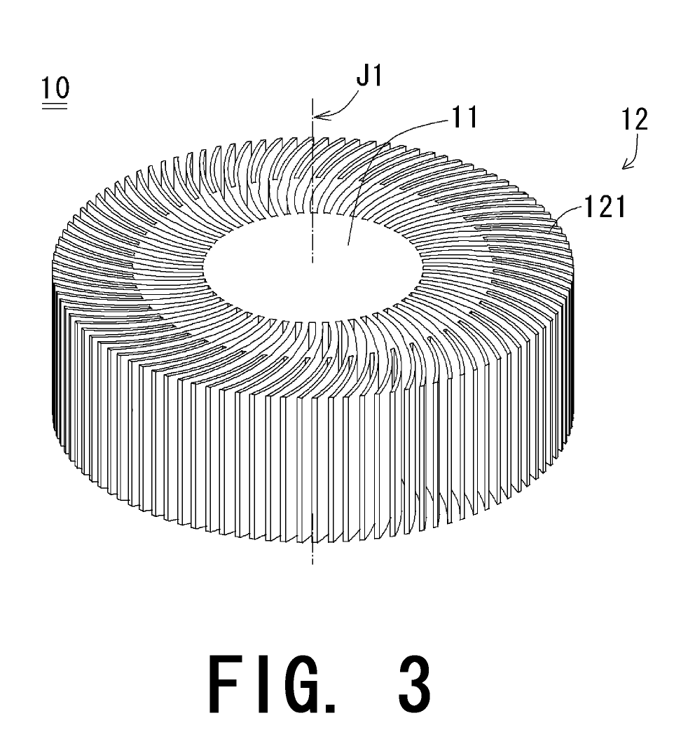

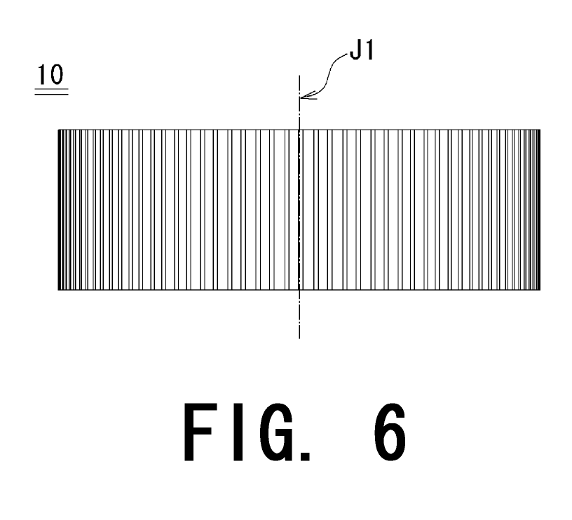

The manufacturing method of the heat sink 1 of this preferred embodiment is now described in more detail. FIGS. 3, 4, and 5 are perspective views of the heat sink in the course of manufacturing. FIGS. 6, 7, and 8 are side views of the heat sink in the course of manufacturing. Please note partially-formed heat sinks are labeled with 10, 101, and 102 in FIGS. 3, 4, 5, 6, 7, and 8.

As described above, aluminum alloy is used as the material of the heat sink 1 in this preferred embodiment. Preferable examples of aluminum alloy are 6000 series aluminum (Al—Mg—Si), and 1000 series aluminum which is primarily unalloyed and has a minimum content of 99% aluminum. Among them, 6063 is often used, which is usually used as structural material not requiring high strength, for example, for architectural components such as sash doors. Since 6063 has good extrudability which is one of the most important properties for making the heat sink, 6063 is used for the heat sink 1 very often. In a case were thermal conductivity is preferred over extrudability, 1060 or 1070 of 1000 series aluminum is used.

The heat sink 1 of this preferred embodiment is formed by directly extruding the molten material of the heat sink 1. This type of extrusion may be called as “direct extrusion” and is performed in the following manner. First, billets of the material of the heat sink 1, i.e., aluminum alloy billets are heated and molten. The molten material is injected into a container in which an extrusion mold is placed, and is pushed toward the mold. The mold has an opening which penetrates through the mold and through which the molten material passes. The cross-sectional shape of the opening on a plane perpendicular to an extrusion direction in which the material is extruded corresponds to the cross-sectional shape of the heat sink 1 on a plane perpendicular to the center axis J1. The molten material is shaped in accordance with the shape of the opening of the mold by passing through the mold and is then extruded from the mold.

The extruded product extends in the extrusion direction. Since the extruded product immediately after being extruded from the mold is hot and soft, it is bowed and twisted. In order to eliminate the bow and twist, the extruded product is stretched from both longitudinal ends. While being straightened, the extruded product is cooled. The shape of the extruded product is made closer to the designed shape through the above operations. Subsequently, this long extruded product is cut by a plane perpendicular to the longitudinal direction, i.e., the center axis J1 of the heat sink, to obtain a partially-formed heat sink 10 having a desired thickness. The partially-formed heat sink 10 immediately after the cutting is shown in FIGS. 3 and 6.

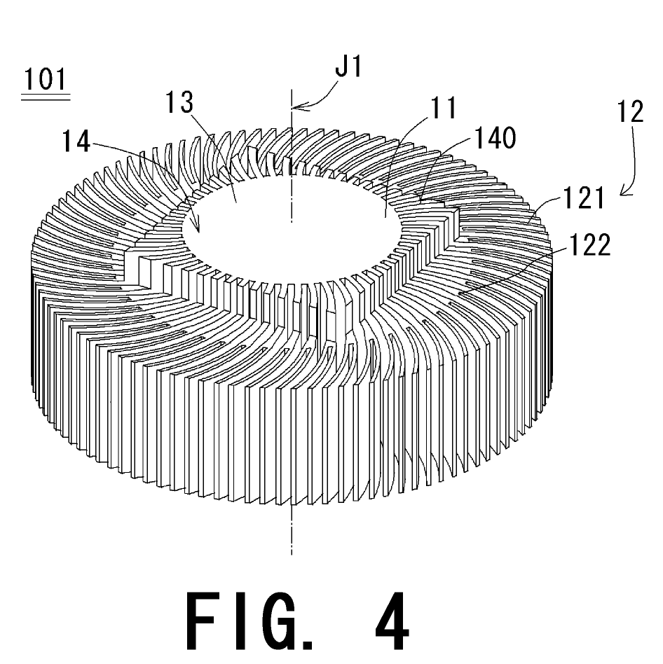

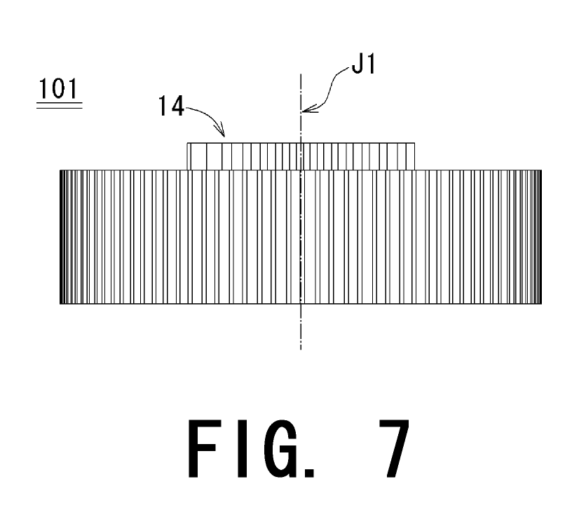

The partially-formed heat sink 10 is then held on a cutting machine, e.g., a CNC milling machine and is subjected to cutting. In this cutting, a portion of the partially-formed heat sink 10, which corresponds to the finned portion 12 of the heat sink 1 (this portion of the partially-formed heat sink 10 is also referred to as the finned portion 12 for the sake of convenience), is cut such that a convex portion 14 which is in the form of a rectangular or substantially rectangular column centered about the center axis J1, for example, projects axially upward from the remaining portion of the finned portion 12. FIGS. 4 and 7 show a state where the convex portion 14 is formed. In this manner, a heat sink 101 having the concave portion 14 is formed.

The convex portion 14 includes the base portion 11 and a finned portion which is a raised portion of the finned portion 12 and is located radially outside the base portion 11. The finned portion of the convex portion 14 includes fins 140. Immediately after the cutting, the profile of the convex portion 14 is formed by the top surface of the base portion 11 and the axially upper ends and radially outer ends of the fins 140. This profile is hereinafter referred to as an envelope of the convex portion 14.

The heat sink 101 held on the milling machine is subjected to further cutting. In this cutting, the side portion of the envelope of the convex portion 14 formed by the outer peripheral ends of the fins 14 is cut such that a recess 143 is formed in the side portion of the envelope of the convex portion 14. The recess 143 is formed by cut portions of the outer peripheral ends of the fins 140 toward the center axis J1. This cutting for forming the recess 143 also forms a projection 142 on the side portion of the envelope of the convex portion 14. The projection 142 projects radially outward, i.e., in a direction away from the center axis J1 and is formed by uncut portions of the outer peripheral ends of the fins 140. The projection 142 and the recess 143 are hereinafter referred to as a radial projection 142 and a radial recess 143 for the sake of convenience, respectively. Through this cutting, a heat sink 102 having the radial projection 142 and the radial recess 143 is obtained.

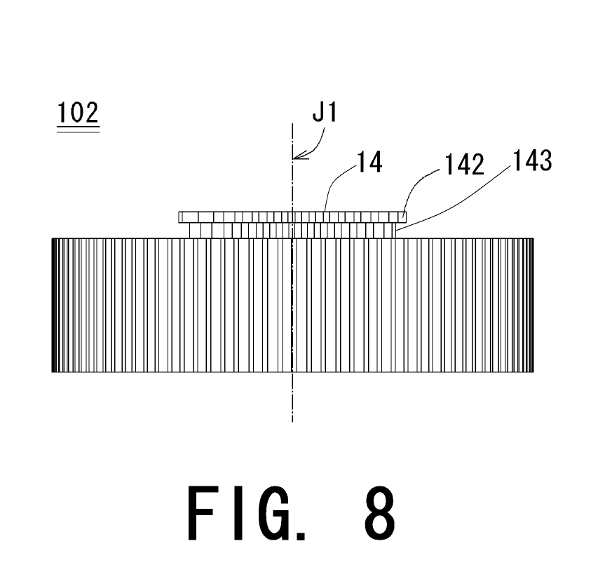

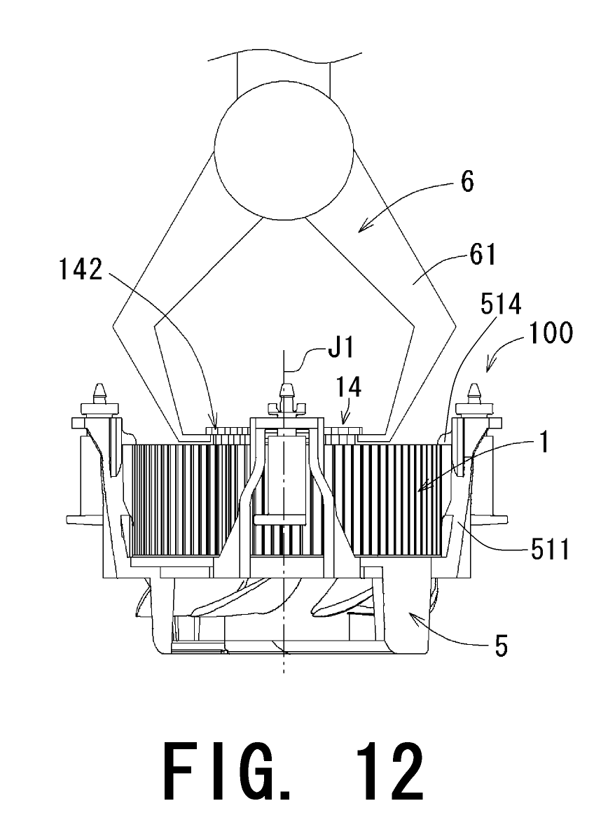

In this preferred embodiment, each of the radial projection 142 and the radial recess 143 is formed by the outer peripheral ends of all the fins 140. That is, each of the radial projection 142 and the radial recess 143 is formed all around the convex portion 14. However, it is not necessary that each of the radial projection 142 and the radial recess 143 be formed by the outer peripheral ends of all the fins 140. The radial projection 142 or the radial recess 143 may be formed by any number of the fins 140, as long as a holding device 6 of an automated manufacturing line, which is shown in FIG. 12 and will be described later, can catch the heat sink stably. In other words, it is only necessary that the radial recess 143 have a shape corresponding to the shape of the tip of an arm 61 of the holding device 6. FIG. 8 shows the partially-formed heat sink 102 when viewed from radially outside.

Subsequently, the top surface of the convex portion 14 (including the top surface of the base portion 11 and the upper ends of the fins 140) is cut such that a columnar portion 130 having a contact surface 13 as its top surface is provided on the top surface of the base portion 11 of the heat sink 102. The contact surface 13 is in direct or indirect contact with an object to be cooled (not shown), e.g., an MPU, when the heat sink 1 as the final product is in contact with the object. The column portion 130 is formed to project from the top surface of the remaining region of the base portion 11 and the upper ends of the fins 140. The thus formed columnar portion 13 and the contact surface 130 are shown in FIG. 1. In this preferred embodiment, the contact surface 13 preferably is substantially circular when viewed along the axial direction and therefore the column portion 130 is in the form of a substantially circular column.

After the contact surface 13 and the column portion 130 are formed, the contact surface 13 is polished to be a finer surface or have surface roughness smaller than that before polishing. Consequently, the area of contact between the heat sink and the object to be cooled is maximized and therefore the contact thermal resistance is minimized. The manufacturing of the heat sink 1 ends with the polishing process. FIG. 1 shows the heat sink 1 as the final product.

In the above description of the manufacturing of the heat sink 1, the outer periphery of the convex portion 14, i.e., the side portion of the envelope of the convex portion 14 is defined by the fins 140 only. However, the outer periphery of the convex portion 14 may be defined by the base portion 11 only or both the fins 140 and the base portion 11. In those cases, however, the manufacturing processes are substantially the same as that described above. Therefore, the detailed description in those cases is omitted here.

The heat sink 1 is manufactured in the above-described manner. The shape of the heat sink 1 is now described. Referring to FIG. 1, the heat sink 1 of this preferred embodiment preferably has a profile of an approximately circular column. The convex portion 14 projects axially upward from the surrounding region of the top surface of the heat sink 1. The convex portion 14 includes the base portion 11 and the raised portion of the finned portion 12, i.e., the fins 140. The convex portion 14 is provided on its outer periphery with the radial projection 142 and the radial recess 143. The diameter of the heat sink 1 is longer at the radial projection 142 than at the radial recess 143 by a difference which is approximately constant.

The radial projection 142 and the radial recess 143 are defined by a plurality of fins 140 as described above. Therefore, when the heat sink 1 is used in a heat sink fan 100 shown in FIG. 12, the radial projection 142 and the radial recess 143 can contribute to dissipation of the heat which is generated in an object to be cooled, e.g., an MPU and transferred to the fins 140.

The heat sink 1 is in contact with an object to be cooled such as an MPU at its contact surface 13 as the top surface of the column portion 130. Thus, even if burrs are generated on the fins 140 in the cutting process and extend toward the object to be cooled or the motherboard on which the object is mounted, the burrs cannot be in contact with the object or another component on the motherboard due to existence of the column portion 130. The height or axial length of the column portion 130 has to be determined considering the possible height of the burrs. In this preferred embodiment, this height is preferably set to about 1.3 mm, for example, but is not limited thereto because the possible height of the burrs may be changed depending on the cutting method. In addition, if strong stress is applied to the inner portions of the fins 140 during the cutting, the fins 140 may be deformed such that their radially outer ends are located axially above their radially inner ends. Even in this case, however, the fins 140 cannot come into contact with a component mounted on the motherboard due to existence of the column portion 130.

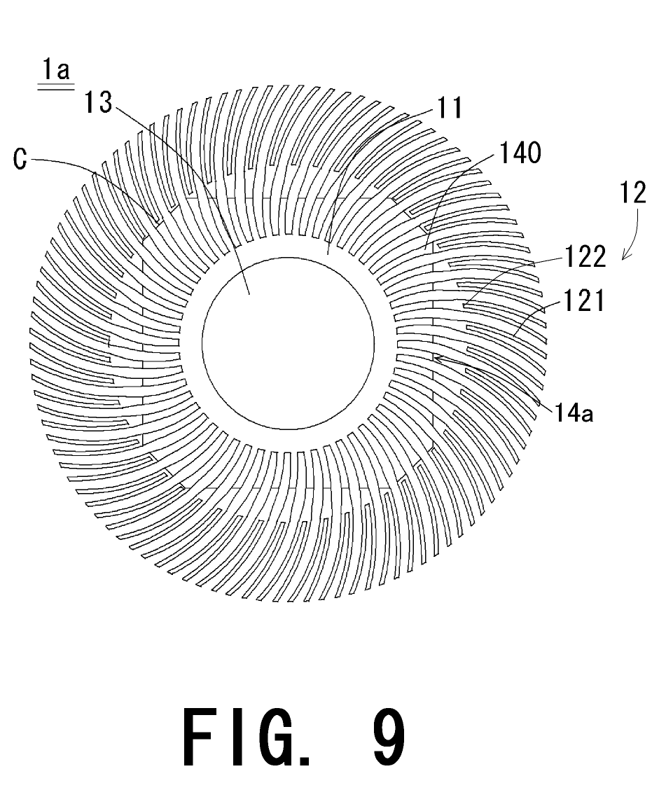

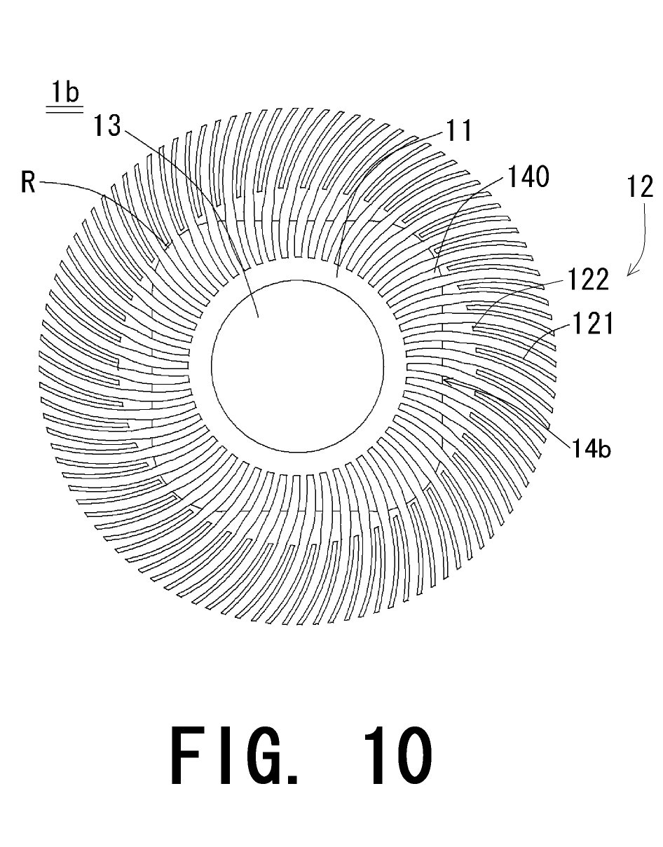

Next, variants of the preferred embodiment of the present invention are described, referring to FIGS. 9 and 10. FIGS. 9 and 10 are top views of the heat sinks 1a and 1b of the variants, respectively.

In the variant of FIG. 9, the heat sink 1a has a convex portion 14a which has a substantially rectangular cross section when viewed from axially above and is the same as the convex portion 14 of the heat sink 1 shown in FIG. 1 except for the shape of its corners. As shown in FIG. 9, when the convex portion 14a is viewed along the axial direction, each of four corners thereof is chamfered substantially at about 45 degrees relative to sides adjacent to the corner. One of advantages of this shape of the convex portion 14a is now described. Each fin of the finned portion 12 is split into two branch fins 121 at the split point 122 located at a radially middle position of the fin. If the split point 122 is included in the convex portion 14a and the branch fins 121 are partially included in the convex portion 14a, the outer periphery of the convex portion 14a is formed by the branch fins 121. This means, on the outer periphery of the convex portion 14a, each branch fin 121 is very thin. Therefore, when cutting is performed to form the convex portion 14a, the branch fins 121 are cut by a cutting machine and may be broken or deformed because of their thinness. That is, the convex portion 14a may not have a desired shape precisely. In order to avoid this, it is necessary that the convex portion 14a do not include the split point 122. One solution is to chamfer the corners substantially at 45 degrees, as shown in FIG. 9.

FIG. 10 shows another solution. In the heat sink 1b, each corner of a convex portion 14b which is rectangular when viewed from axially above is round-chamfered. Except for this, the convex portion 14b is the same as that of the heat sink 1 shown in FIG. 1. With these shapes of FIGS. 9 and 10, it is possible to form the radial projection 142 and the radial recess 143 on the outer periphery of the convex portion 14a or 14b without damaging the convex portion 14a or 14b. Also, the thus formed convex portions 14a and 14b have sufficient strength after formation of the radial projection 142 and the radial recess 143, e.g., while the heat sink is carried by being caught at the radial recess 143.

The shape of the heat sink is not limited to the above. That is, the heat sink can have any shape as long as the convex portion 14, 14a, or 14b does not include the split point 122 and the branch fin 121 of the finned portion 12.

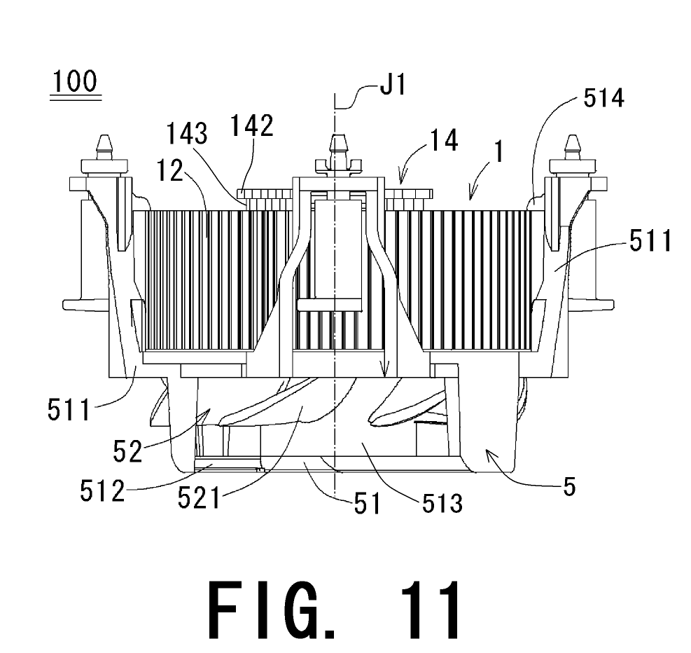

FIG. 11 is a side view of a heat sink fan in which a fan 5 is attached above the heat sink 1. The heat is transferred from an object to be cooled, e.g., an MPU in this preferred embodiment to the base portion 11 (see FIG. 1) of the heat sink 1 directly or through a heat transfer member (not shown). Then, the heat is transferred from the base portion 11 to the finned portion 12. In this preferred embodiment, air is delivered to the finned portion 12 of the heat sink 1 while the fan 5 is rotated, thereby radiating the heat transferred to the finned portion 12 forcedly. The structure of the fan 5 is now described.

The fan 5 includes an impeller 52 which can rotate about a rotation axis to generate an air flow, an electric motor (not shown) for rotating the impeller 52, a surrounding wall portion 513 which converts the air flow into a static-pressure energy, a base portion 51 to which the electric motor is fixed, and at least three spokes 512 connecting the base portion 51 and the surrounding wall portion 513 to each other. In this preferred embodiment, the fan 5 is substantially coaxially arranged with the heat sink 1 and therefore the rotation axis of the impeller 52 is substantially coincident with the center axis J1 of the heat sink 1. The surrounding wall portion 513, the base portion 51, and the spokes 512 form a housing which accommodates the impeller 52 and the electric motor therein.

The impeller 52 has a plurality of blades 521 which are arranged and turned about the rotation axis of the impeller 52 with rotation of the impeller 52. The blades 521 extend radially outward. While the impeller 52 is rotating, the blades 521 provide kinetic energy to air. Rotation of the impeller 52 generates an air flow flowing axially upward. The thus formed air flow has a centrifugal component directed radially outward, a swirling component directed along a rotation direction of the impeller 52, and an axial component directed in the axial direction. The velocity of the air flow is the largest in a radially outer region of the impeller 52 and is the smallest in a radially inner region thereof. Thus, the air flow flowing to the heat sink 1 has the largest velocity in a radially outer region of the finned portion 12.

The fan 5 is arranged below the heat sink 1 with the center axis J1 of the base portion 11 substantially coincident with the rotation axis of the impeller 52 of the fan 5, as shown in FIG. 11. The housing is provided with a plurality of arms 511 which extend upward from the surrounding wall portion and are arranged to catch the heat sink 1 at their upper ends. More specifically, each arm 511 has an engagement portion 512 at its upper end. The engagement portion 512 engages with the top surface of the heat sink in FIG. 11, i.e., the surface of the heat sink 1 opposite to the fan 5, thereby securing the heat sink 1 and the fan 5 to each other. An object to be cooled, e.g., an MPU, is arranged on the upper side of the heat sink 1 in FIG. 11, i.e., on the opposite side to the fan 5, although it is not shown.

The heat generated in the object is transferred to the base portion 11 of the heat sink 1. In this preferred embodiment, the heat is transferred through a heat transfer member sandwiched between the object and the heat sink 1. The heat is then transferred to the finned portion 12 to which an upward air flow generated by rotation of the fan 5 is delivered. The fins of the finned portion 12 are arranged about the center axis J1 of the heat sink 1 with circumferential spaces between adjacent fins. Therefore, the air flow passes through spaces between the adjacent fins, thereby radiating the heat transferred to the fins of the finned portion 12. In this manner, the cooling or heat radiating performance of the heat sink 1 can be improved by being combined with the fan 5.

In this preferred embodiment, each fin of the finned portion 12 is curved such that its radially outer end is located on the upstream side of its radially inner end in the rotation direction of the impeller 52. With this configuration, it is possible to reduce interference of the air flow generated by rotation of the impeller 52 with the fins of the finned portion 12, thus reducing noises caused the interference.

Although the fins of the finned portion 12 preferably are curved in the above-described manner in this preferred embodiment, it is not always that the fins are curved. The interference of the air flow from the fan 5 with the fins of the finned portion 12 can be reduced to a satisfactory level only by arranging each straight fin at an angle to the radial direction such that its radially outer end is located on the upstream side of its radially inner end in the rotation direction of the impeller 52. Moreover, even in a case where each fin extends straight in the radial direction, the interference of the air flow with the fins of the finned portion 12 can be reduced to a certain extent because each blade 521 of the impeller 52 is curved such that its radially outer end is located on the downstream side of its radially inner end in the rotation direction of the impeller 52.

Next, exemplary processes for assembling the heat sink 1 with the fan 5 into a heat sink fan 100, carrying the thus assembled heat sink fan 100, and mounting the heat sink fan 100 onto a circuit board on which an MPU as an object to be cooled is mounted are described, referring to FIG. 12. FIG. 12 shows the heat sink 1 being held at its radial projection 142 by a holding device 6 while being carried.

First, the manufacturing process of the heat sink fan 100 is described. The heat sink fans 100 are usually manufactured in automated manufacturing lines in each of which information on the position and shape of each of the heat sinks and the fans is stored and which is controlled based on that information. The heat sinks 1 are put and arranged on a tray for each of which information on the position thereof is managed. Then, the holding device 6 is controlled to catch the radial projection 142 of one heat sink 1 and carry the heat sink 1 to an assembly position where the fan 5 to be assembled therewith is arranged. At the assembly position, the fan 5 is fixed with its side on which the heat sink 1 is mounted set toward a direction from which the heat sink 1 is moved to the heat sink 1. In other words, if the heat sink 1 is mounted above the fan 5, as in the example of FIG. 12, the fan 5 is placed with its side opposite to the base portion 51 (see FIG. 11) facing up and the arms 511 extending upward. The holding device 6 then places the carried heat sink 1 in position, for example, on the fan 5. The engagement portions 514 of the arms 511 engage with the heat sink 1. In this preferred embodiment, the engagement portions 514 engage with the top surface of the heat sink 1. In this manner, the heat sink 1 is assembled with the fan 5. A plurality of heat sink fans 100 are successively assembled by repeating above operations. The thus assembled heat sink fan 100 is then mounted on the circuit board with the MPU mounted thereon.

The heat sink fans 100 of this preferred embodiment of the present invention are used for radiating the heat mainly generated in MPUs to ambient air. In particular, the heat sink fans 100 are suitable for MPUs for desktop personal computers. In this preferred embodiment, a single heat sink fan 100 is preferably used with a single MPU. Desktop personal computers are widely used all over the world and MPUs the number of which depends on the number of manufactured desktop personal computers are shipped. Therefore, the heat sink fan 100 must be suitable for mass production. The mass production requires automated production lines and, for this reason, the heat sink fan 100 of this preferred embodiment has a shape suitable for automated production.

In this preferred embodiment, the heat sink fan 100 is placed on a tray with the fan 5 located below the heat sink 1, as shown in FIG. 11. The holding device 6 provided in the automated production line catches the radial projection 142 of the heat sink fan 100 on the tray, as shown in FIG. 12. The holding device 6 is a two-fingered robot hand, for example. The holding device 6 picks the heat sink fan 100 out of the tray and then carries the heat sink fan 100.

Since the heat sink fan 100 is a precision component, it is necessary to prevent the finned portion 12 and the fan 5 from being damaged, scratched, or the like. If relatively strong holding force is applied to the heat sink fan 100, the finned portion 12 may be damaged or deformed. Therefore, strong holding force is not preferable. For this reason, the heat sink fan 100 is not grasped by the holding device 6 but is axially hooked at the radial projection 142, so as to be lifted axially and vertically to the ground and then carried. Thus, the load applied to the heat sink fan 100 is the weight of the heat sink fan 100 only. The radial projection 142 is designed to have such an axial length that the radial projection 142 can stand up under the weight of the heat sink fan 100.

The holding device 6 has two fingers 61 which can move close to radially facing portions of the radial projection 142. The fingers 61 hook the radially facing portions of the radial projection 142 from radially outside. Moreover, a line connecting the fingers 61 to each other crosses the center axis J1 of the heat sink fan 100. Thus, the heat sink fan 100 can be stably carried by the holding device 6. In a case where the convex portion 14 is in the form of a circular column, if a line on which the two fingers 61 of the holding device 6 is slidable does not cross the center axis J1, the fingers 61 may slip on the outer periphery of the convex portion 14 and may not be able to grasp the radial projection 142. Considering the above, the holding device 6 is arranged such that it can stably and precisely catch the heat sink fan 100.

The thus hooked heat sink fan 100 is carried and placed at a position above the circuit board on which the MPU is mounted. Then, the heat sink fan 100 is positioned such that the contact surface 13 of the base portion 11 is in close contact with the MPU, and is then fixed to the circuit board. The strength of fixing is ensured sufficiently considering the load of the heat sink fan 100 and vibration caused by rotation of the fan.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A heat sink for cooling an object, comprising:
a base portion centered about a center axis; and
a finned portion including a plurality of fins arranged about the center axis, the fins extending outward from the base portion in a radial direction perpendicular to or substantially perpendicular to the center axis; wherein
a convex portion is located at one of axial ends of the heat sink, is defined by at least a raised portion of the base portion, and is provided on an outer peripheral surface thereof, with a projection projecting away from the center axis.

2. The heat sink according to claim 1, wherein the convex portion is defined by the raised portion of the base portion at one of axial ends thereof without including the finned portion.

3. The heat sink according to claim 1, the convex portion is defined by the raised portion of the base portion and a raised portion of the finned portion.

4. The heat sink according to claim 3, wherein an outer periphery of the convex portion is defined by outer periphery of the raised portion of the finned portion.

5. The heat sink according to claim 1, wherein the convex portion has a substantially rectangular shape when viewed along the axial direction.

6. The heat sink according to claim 1, wherein the convex portion has an approximately rectangular shape with corners that are round-chamfered when viewed along the axial direction.

7. The heat sink according to claim 1, wherein the convex portion has an approximately rectangular shape with corners that are chamfered at approximately 45 degrees, when viewed along the axial direction.

8. The heat sink according to claim 1, wherein each of the fins of the finned portion is split into at least two portions at a split point between its radially inner end and its radially outer end.

9. The heat sink according to claim 8, wherein no split point is included in the convex portion.

10. The heat sink according to claim 1, wherein the base portion includes a columnar portion and a surrounding portion surrounding the columnar portion, the columnar portion projecting from the surrounding portion and having smaller surface roughness at its axial end than that of an axial end of the surrounding portion.

11. The heat sink according to claim 1, wherein a recess is arranged axially between the projection and a remaining portion of the base portion, a diameter of the heat sink being longer at the projection than at the recess.

12. The heat sink according to claim 11, wherein the recess is arranged over a portion of a circumferential length of the heat sink.

13. The heat sink according to claim 11, wherein a diameter of the heat sink is longer than the projection than at the recess stance by an approximately constant difference.

14. A heat sink fan comprising:
the heat sink according to claim 1; and
a fan arranged to supply an air flow to the heat sink, wherein the fan includes:
an impeller rotatable about a rotation axis and having a plurality of blades arranged to generate the air flow while the impeller is rotating;
a motor arranged to drive the impeller; and
a housing having a surrounding wall portion which surrounds the impeller from outside in the radial direction and supports the motor; wherein
the heat sink and the fan are arranged with the center axis of the base portion and the rotation axis of the impeller substantially coaxial with each other.

15. A method for manufacturing a heat sink fan as recited in claim 14, comprising:
hooking the heat sink at the projection and carrying the heat sink;
placing the heat sink at an assembly position where the fan is placed; and
securing the heat sink and the fan to each other.
